(19) United States
(12) Patent Application Publication
(10) Pub. No.: US 2018/0305807 A1
(43) Pub. Date: Oct. 25, 2018

(54) METHOD OF FORMING CARBON FILM

(71) Applicant: ULVAC, INC., Kanagawa (JP)

(72) Inventors: Shinji Kohari, Kanagawa (JP); Junichi Itoh, Kanagawa (JP); Kazushi Fuse, Kanagawa (JP); Mitsunori Henmi, Kanagawa (JP)

(73) Assignee: ULVAC, INC., Kanagawa (JP)

(21) Appl. No.: 15/768,612

(22) PCT Filed: Aug. 22, 2016
(86) PCT No.: PCT/JP2016/003800

§ 371 Date: Apr. 16, 2018

(30) Foreign Application Priority Data
Nov. 20, 2015 (JP) 2015-228097

(51) Int. Cl. C23C 14/35; C23C 14/06

(52) U.S. Cl. CPC C23C 14/35; C23C 14/0605

(57) ABSTRACT

In a method of forming a carbon film of this invention, a target made of carbon is used, and in a state in which leakage magnetic field Mf is being functioned on a front surface side of the target, electric power is applied to the target to sputter, thereby forming a carbon film on a surface of a to-be-processed object. At this time, a region for the leakage magnetic field to function on the target surface is made local, and the region for the leakage magnetic field to function is periodically changed by relatively moving the region relative to the target from an origin on the target surface back to the origin. Also, a product of an average magnetic field strength of the leakage magnetic field at a predetermined position on the target surface and applied electric power is kept below 125 G·kW.

### TECHNICAL FIELD

The present invention relates to a method of forming a carbon film and, in particular, to the method by means of a magnet sputtering method.

### BACKGROUND ART

It is known that a carbon film is used as electrodes for devices such as memory elements, organic EL elements, and the like. For film formation of this kind of carbon film, a so-called magnetron type of sputtering apparatus is used in view of the ease of mass-productivity and the like (see, for example, Patent Documents 1, 2). This kind of sputtering apparatus is equipped with a vacuum chamber having a stage on which is disposed a to-be-processed object which is to be subjected to film forming processing. Inside the vacuum chamber a sputtering cathode is disposed in a manner to lie opposite to the stage. The sputtering cathode is provided with: a target made of carbon such as graphite, pyrolytic carbon, and the like; and a magnet unit which causes leakage magnetic field to function on a target surface. In forming a carbon film, sputtering gas for discharging such as argon gas is introduced into the vacuum chamber which is in vacuum atmosphere; high frequency power and the like is applied to the target to thereby generate plasma in the space between the stage and the target; the target is thus sputtered by the ions of the sputtering gas in the plasma, whereby a carbon film is formed on a surface of that to-be-processed object on the stage which is disposed in a manner to lie opposite to the target.

In the above-mentioned kind of sputtering apparatus, in order to improve the uniformity in film thickness of the carbon film, and the utilization efficiency of the target, the following is generally practiced. In other words, for example, in case the target has a circular profile, the magnet unit is unevenly distributed off the center of the target so that the region in which the leakage magnetic field functions on the target surface becomes local. During film forming, by rotating the magnet unit at a constant speed about the center of the target serving as the center of rotation, the region in which the leakage magnetic field functions is periodically changed to make a relative movement against the target from an origin on the target surface back to the origin.

However, when the carbon film is formed according to the above-mentioned prior art example, it has been found that the specific resistance of the carbon film cannot effectively be lowered. In other words, only a carbon film having a specific resistance of about several Ω ·cm can be obtained. Therefore, the inventors of this invention made strenuous efforts to finally obtain a finding that the magnetic field strength of the leakage magnetic field that functions on the target surface in relation to the electric power applied to the target may sometimes serve to be an obstacle to the lowering of the specific resistance of the carbon film.

### PRIOR ART DOCUMENT

Patent Document
Patent Document 1: JP-1996-31573 A
Patent Document 2: International Publication No. 2015-122159

### SUMMARY OF THE INVENTION

### Problems that the Invention is to Solve

Based on the above finding, this invention has been made and has a problem of providing a method of forming a carbon film which enables to form a carbon film having an extremely low specific resistance, as compared with that of an example of prior art, of about several tens of Ω·cm can be obtained with good reproducibility.

### Means of Solving the Problems

In order to solve the above problems, the method of forming a carbon film according to this invention comprises: by using a target made of carbon, sputtering by applying electric power to the target in a state in which a leakage magnetic field is caused to function on a surface of this target, thereby forming a carbon film on a surface of a to-be-processed object, wherein a region for the leakage magnetic field to function on the target surface side is made local and wherein the region for the leakage magnetic field to function is periodically changed by relatively moving the region relative to the target from an origin on the target surface back to the origin. The method is characterized in that a product of an average magnetic field strength of the leakage magnetic field at a predetermined position on the target surface and applied electric power to the target is kept below 125 G·kW.

According to this invention, it has been confirmed that a carbon film having a specific resistance below 30 Ω·cm (in case the above-mentioned product is below 85 G·kW and also in case the above-mentioned average magnetic field strength is below 50 G, below 20 Ω·cm) can be formed with good reproducibility, and that a carbon film with a still lower specific resistance than the above-mentioned example of the prior art can be obtained. Here, the term “average magnetic field strength” means an average value of the magnetic field strength at a predetermined position on the target surface when the magnet unit is subjected to a relative movement at a predetermined speed. In other words, when reference is made to the magnetic field strength near the target surface at the predetermined position, within one cycle, the magnetic field strength from zero increases accompanied by an approach of the magnet unit, and the magnetic field strength will then attain a maximum value. Subsequently, with a movement of the magnet unit away, the magnetic field strength decreases and finally the magnetic field strength becomes zero. The above-mentioned term means an average value of the magnetic field strength, within one cycle, at the predetermined position on the target surface. Further, respective minimum values of the average magnetic field strength of the leakage magnetic field and the electric power to be applied to the target surface at the predetermined position of the target surface shall be selected appropriately within a range capable of discharging at the time of sputtering of the target. When the electric power to be applied to the above-mentioned target exceeds 3 kW, a problem has been confirmed to occur that the surface of the carbon film formed on the surface of the to-be-processed object will become rough.

### BRIEF DESCRIPTION OF THE DRAWINGS

FIG. 1 is a schematic sectional view of a magnetron type of sputtering apparatus that can be used in a method of forming a carbon film according to an embodiment of this invention.

FIG. 2 is a figure to explain the relative movement of the magnet unit against the target.

FIGS. 3 (a) and (b) are graphs showing the experiment results to confirm the effects of this invention.

### MODES FOR CARRYING OUT THE INVENTION

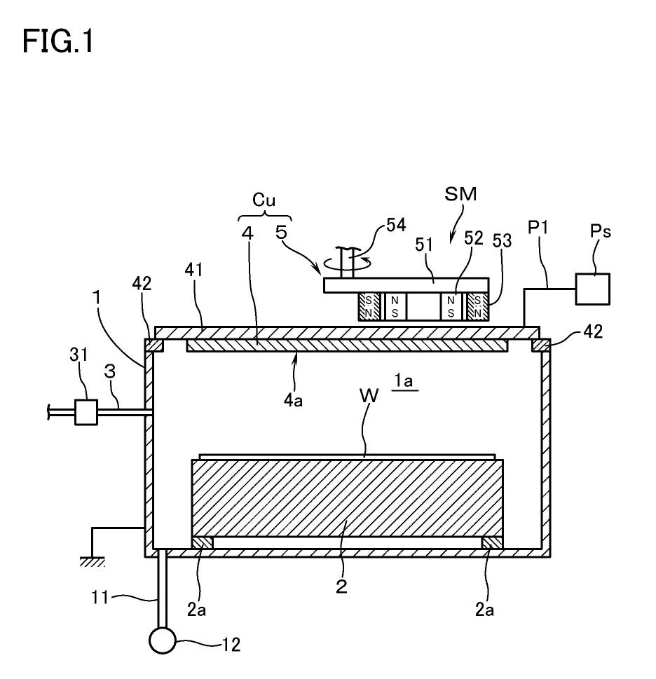

With reference to the drawings, description will now be made of an embodiment of a method of forming a carbon film of this invention, with a silicon wafer W serving as a to-be-processed object, by referring to an example of forming a carbon film on one surface of a silicon wafer W by means of a magnetron type of sputtering apparatus SM. In the following, description will be made with the posture of the sputtering apparatus SM as shown in FIG. 1 serving as a basis, a ceiling wall side of the vacuum chamber being defined as “up (or upper)” and the bottom wall side thereof being defined as “down (or lower).”

With reference to FIG. 1, reference mark “SM” denotes a magnetron type of sputtering apparatus which is used in carrying out the method of forming a film of this embodiment. The sputtering apparatus SM is provided with a vacuum chamber 1 which defines a film forming chamber 1a. The bottom wall of the vacuum chamber 1 has connected thereto an exhaust pipe 11. The exhaust pipe 11 has connected thereto a vacuum pump 12 which is made up, e.g., of a turbo molecular pump and a rotary pump on an exhaust pressure side so as to evacuate the inside of the film forming chamber 1a to a predetermined pressure (e.g., 10⁻⁵ Pa). On the bottom wall of the vacuum chamber 1 there is disposed, through an insulating member 2a, a stage 2 on which is placed in position a silicon wafer W. In this case, an electrostatic chuck mechanism may alternatively be assembled on the stage 2 so that the silicon wafer W can be held by suction.

In addition, a side wall of the vacuum chamber 1 has connected thereto a gas introduction pipe 3 which is connected to a gas source (not illustrated) and which has interposed therein a mass flow controller 31. It is thus so arranged that a sputtering gas for electric discharging such as argon can be introduced into the film forming chamber 1a at a predetermined flow rate. On a ceiling wall of the vacuum chamber 1, there is disposed a cathode unit Cu. The cathode unit Cu is provided with a target 4 made of carbon, and a magnet unit 5 which causes leakage magnetic field to function on the lower surface side of the target 4.

The target 4 is constituted by graphite, pyrolytic carbon, and the like which is appropriately selected depending on the thin film (carbon film) that is going to be formed. The target 4 is manufactured by a known method so as to have a circular profile. Further, to an upper surface of the target 4 there is bonded, through a bonding material (not illustrated), a backing plate 41 made of copper. By means of that portion of the backing plate 41 which is elongated outward beyond the target 4, the backing plate 41 is mounted, through an insulating material 42, on the ceiling wall of the vacuum chamber 1 such that the lower surface (sputtering surface 4a) of the target 4, as the target 4 surface, faces the film forming chamber 1a. In this case, the distance in the vertical direction between the sputtering surface 4a and the silicon wafer W on the stage 2 is set to 40˜90 mm. Furthermore, the target 4 (backing plate 41) has connected thereto an output cable P1 from a sputtering power source Ps which is constituted by a RF power source (13.56 MHz) or a DC pulse power source (e.g., 80 kHz˜400 kHz) of a known construction so that predetermined electric power can be applied. By the way, other RF power sources for applying bias voltage to the silicon wafer W on the stage 2 may be disposed.

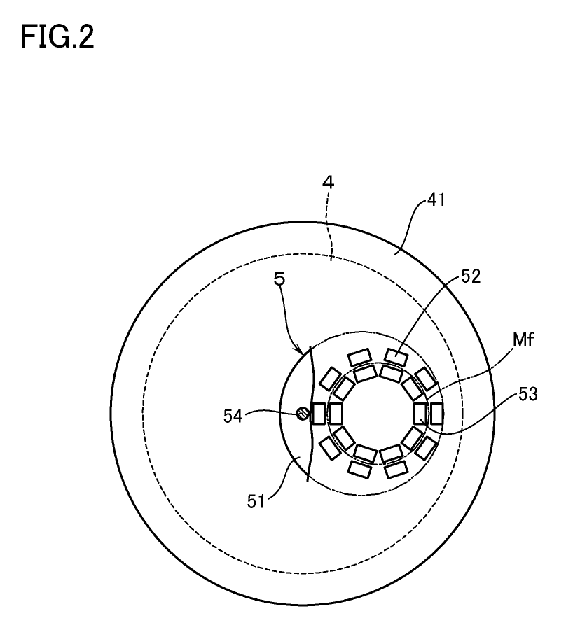

With reference also to FIG. 2, the magnet unit 5 which is disposed above the backing plate 41 has a disk-shaped supporting plate 51 as a yoke which is made of a magnetic material. On a lower surface of the supporting plate 51 there are disposed outside magnets 52 which are arranged along an arc of a diameter smaller than the target 4, and inside magnets 53 which are arranged along an arc of a predetermined diameter on the inside of the outside magnets 52, while changing the polarities on the side of the target 4. In this case, as the outside magnets 52 and the inside magnets 53, neodymium magnets of the same magnetization are used. For example, a ring-shaped one formed integrally may be used. According to this arrangement, leakage magnetic field Mf will be locally functioned on a predetermined region on the sputtering surface 4a of the target 4. Further, the supporting plate 51 has connected thereto a driving shaft 54 which is disposed to coincide with an axial line passing through the center of the stage 2. It is thus so arranged that, by driving to rotate the driving shaft 54 by driving means such as a motor and the like (not illustrated), the supporting plate 51 rotates at a certain rotational speed. According to this arrangement, the region in which the leakage magnetic field Mf functions can be periodically changed by making a relative movement against the target 4 from an origin of the target 4 surface back to the origin.

The above-mentioned sputtering apparatus SM has a known control means (not illustrated) provided, e.g., with a microcomputer, sequencer, and the like so as to make an overall control over the operations of the mass flow controller 31, vacuum pump 12 and the sputtering power source Pa to thereby form a carbon film on the surface of the silicon wafer W. Description will hereinafter be made in concrete of a method of forming a carbon film based on an example of forming a carbon film on a silicon wafer W surface, with the target 4 being made of graphite, by using the above-mentioned sputtering apparatus SM.

In a state in which a silicon wafer W is placed in position on the stage 2, the film forming chamber 1a is evacuated and, when it has reached a predetermined pressure (e.g., 1×10⁻⁵ Pa), the mass flow controller 31 is controlled to introduce argon gas at a predetermined flow rate. In this case, the flow rate of the sputtering gas is set such that, in relation to the exhaust gas speed of the vacuum pump 12, the pressure in the film forming chamber 1a falls in a range of 0.01˜30 Pa. Then, RF power is applied from the sputtering power source Ps to the target 4. According to these operations, annular plasma is generated in a region which is the space between the silicon wafer W on the stage 2 and the target 4 and in which the leakage magnetic field Mf functions by the magnet unit 5. The target 4 gets sputtered by the argon ions in the plasma and, consequently, the sputtered particles will be spread, and get adhered to the silicon wafer W surface and deposited to thereby form a carbon film. In this case, the magnet unit 5 is rotated at a speed within a range of 30˜90 rpm.

Here, according to the finding of the inventors of this invention, the magnetic field strength of the leakage magnetic field Mf from the magnet unit 5 may sometimes serve to be an obstacle to the lowering of the specific resistance of the carbon film. Therefore, in this embodiment, by appropriately setting the magnets which respectively constitute the outside magnets 52 and the inside magnets 53 of the magnet unit 5, the product of an average magnetic field strength of the leakage magnetic field Mf at a predetermined position on the target 4 surface and the applied electric power to the target 4 (electric power on the sputtering power source side) is kept below 125 G·kW. In this case, the term “average magnetic field strength” means an average value of the magnetic field strength at a predetermined position on the target 4 surface when the magnet unit 5 is rotated by the driving means at a predetermined speed. In other words, when reference is made to the magnetic field strength near the predetermined position on the target 4 surface, within one cycle, the magnetic field strength increases from zero, accompanied by an approach of the magnet unit, and finally the magnetic field strength becomes maximum. Subsequently, with a movement of the magnet unit away, the magnetic field strength decreases and the magnetic field strength will finally become zero. The above-mentioned term means an average value of the magnetic field strength, within one cycle, at the predetermined position on the target 4 surface. In addition, the applied electric power to the target 4 at the sputtering power source Ps was made to be below 3 kW. At this time, minimum values of the average magnetic field strength of the leakage magnetic field Mf and the electric power to be applied to the target 4 at the predetermined position of the target 4 surface shall, respectively, be selected appropriately within a range capable of discharging at the time of sputtering the target 4. However, when the electric power to be applied to the above-mentioned target 4 exceeds 3 kW, a problem occurs that the surface of the carbon film formed on the wafer W surface will become rough.

According to the above-mentioned embodiment, a carbon film having a specific resistance below 30 Ω·cm (in case the above-mentioned product is below 85 G·kW and also in case the above-mentioned average magnetic field strength is below 50 G, below 20 Ω·cm) can be formed with good reproducibility, and a carbon film with a still lower specific resistance than the above-mentioned example of the prior art can be obtained.

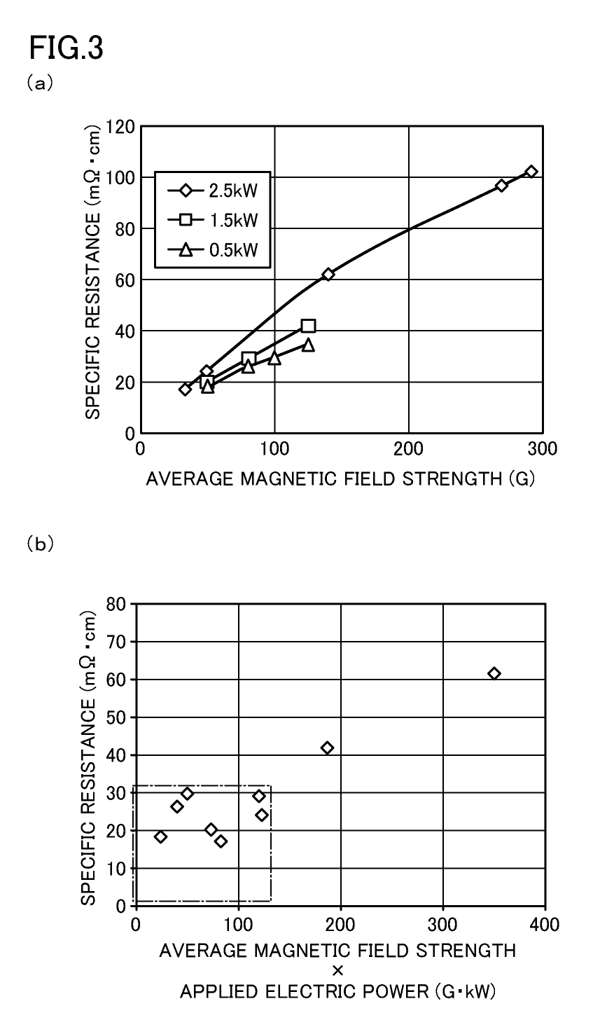

Next, description will now be made of experiments to confirm the effects that can be obtained by carrying out this invention. As the sputtering conditions, the vertical distance between the sputtering surface 4a of the target 4 made of graphite and the silicon wafer W on the stage 2 was made to be 70 mm, the pressure in the film forming chamber 1a was made to be 0.6 Pa, and the rotational speed of the magnet unit 5 was made to be 60 rpm. Then, the electric power to be applied by the sputtering power source Ps to the target 4 was set to be 0.5 kW, 1.5 kW and 2.5 kW, respectively. The average magnetic field strength was appropriately changed within a range of 30˜300 G. The specific resistance of the carbon film in relation to the then average magnetic field strength, as well as the specific resistance in relation to the product of an average magnetic field strength of the leakage magnetic field Mf at a predetermined position on the target 4 surface and the applied electric power to the target 4 (G·kW) are respectively shown in FIG. 3(a) and FIG. 3(b).

According to these graphs, provided that the applied electric power is made to be 2.5 kW, the average magnetic field strength may be set to 50 G. Then, as compared with the example of the prior art, it has been confirmed that a carbon film of extremely low specific resistance of 30 Ω·cm can be obtained. Further, in case the applied electric power is as low as 1.5 kW and 0.5 kW, even if the average magnetic field strength is increased to 80 G and 100 G, confirmation was made that a carbon film of extremely low specific resistance could be obtained in a similar manner as in the above-mentioned case. As a result, it has been confirmed that, if the applied electric power is small, the average magnetic field strength nay be made larger. According to the above, the following confirmation has been made. Namely, if the product of an average magnetic field strength of the leakage magnetic field Mf and the power to be applied to the target 4 at a predetermined position on the target 4 surface is controlled so as to keep the product below 125 G·kW, it has been confirmed that a carbon film having a specific resistance below 30 Ω·cm (in case the above-mentioned product is below 85 G·kW and also in case the above-mentioned average magnetic field strength is below 50 G, below 20 Ω·cm) can be formed with good reproducibility. By the way, although the rotational speed of the magnet unit 5 during sputtering was changed, it has been confirmed that the specific resistance of the obtained carbon film showed little or no changes.

Description has so far been made of an embodiment of this invention, but this invention shall not be limited to the above. In the above-mentioned embodiment, description was made of an example in which the target 4 made of carbon had a circular profile, but this invention shall not be limited to the above, but the profile may be made, for example, to be rectangular. Further, the embodiment of the magnet unit 5 shall not be limited to the above, but may be appropriately changed depending on the profile and the like of the target 4. On this occasion, the relative movement of the magnet unit 5 against the target 4 may, for example, be arranged to be reciprocally moved on the same line.

### Explanation of Reference Characters

4 target
5 magnetron unit
Mf leakage magnetic field
Ps RF power source (sputtering power source)
W silicon wafer (to-be-processed object)

1. A method of forming a carbon film comprising: by using a target made of carbon, sputtering by applying electric power to the target in a state in which a leakage magnetic field is caused to function on a target surface side, thereby forming a carbon film on a surface of a to-be-processed object, wherein a region for the leakage magnetic field to function on the target surface is made local and wherein the region for the leakage magnetic field to function is periodically changed by relatively moving the region relative to the target from an origin on the target surface back to the origin,
wherein a product of an average magnetic field strength of the leakage magnetic field at a predetermined position on the target surface and applied electric power to the target is kept below 125 G·kW.

2. The method of forming a carbon film according to claim 1, wherein the product of the average magnetic field strength of the leakage magnetic field at the predetermined position on the target surface and the electric power applied to the target is kept below 85 G·kW, and wherein the average magnetic field strength is kept below 50 G.

3. The method of forming a carbon film according to claim 1, wherein the electric power applied to the target is kept below 3 kW.

4. The method of forming a carbon film according to claim 2, wherein the electric power applied to the target is kept below 3 kW.
